(19) United States
(12) Patent Application Publication
(10) Pub. No.: US 2024/0194514 A1
(43) Pub. Date: Jun. 13, 2024

(54) SUBSTRATE SUPPORT AND SUBSTRATE PROCESSING APPARATUS

(71) Applicant: Tokyo Electron Limited, Tokyo (JP)

(72) Inventor: Makoto KATO, Miyagi (JP)

(73) Assignee: Tokyo Electron Limited, Tokyo (JP)

(21) Appl. No.: 18/586,860

(22) Filed: Feb. 26, 2024

Related U.S. Application Data
(63) Continuation of application No. PCT/JP2022/031012, filed on Aug. 17, 2022.
(60) Provisional application No. 63/237,813, filed on Aug. 27, 2021.

(30) Foreign Application Priority Data
Feb. 15, 2022 (JP) 2022-021526

(51) Int. Cl. H01L 21/683; H01J 37/32

(52) U.S. Cl. CPC H01L 21/6833; H01J 37/32642; H01J 37/32715; H01J 2237/2007

(57) ABSTRACT

A substrate support disposed inside a plasma processing chamber includes a base electrically connected to at least one power supply, a first dielectric disposed on the base and having a substrate support surface, and a second dielectric disposed on the base to surround the first dielectric and having a ring support surface, wherein the first dielectric includes therein a first heat transfer gas diffusion space, a first electrode disposed above the first heat transfer gas diffusion space, and a conductor that electrically connects the first electrode and the base, and wherein the second dielectric includes therein a second heat transfer gas diffusion space, and a second electrode disposed above the second heat transfer gas diffusion space and electrically connected to a power supply that outputs a common voltage with the base.

### CROSS-REFERENCE TO RELATED APPLICATIONS

This application is a bypass continuation application of International Patent Application No. PCT/JP2022/031012 having an international filing date of Aug. 17, 2022 and designating the United States, the international application being based upon and claiming the benefit of priority from U.S. Patent Application No. 63/237,813, filed on Aug. 27, 2021, and Japanese Patent Application No. 2022-021526, filed on Feb. 15, 2022, the entire contents of each are incorporated herein by reference.

### TECHNICAL FIELD

The present disclosure relates to a substrate support and a substrate processing apparatus.

### BACKGROUND

Patent Document 1 discloses a stage having a substrate placement surface on which a substrate is placed and an edge ring placement surface on which an edge ring is placed. In Patent Document 1, a gas supply pipe is provided inside the stage, and a heat transfer gas such as helium gas is supplied between a back surface of the substrate and the substrate placement surface and between a back surface of the edge ring and the edge ring placement surface via the gas supply pipe.

### PRIOR ART DOCUMENT

### Patent Document

Patent Document 1: Japanese Patent Laid-open Publication No. 2021-141277

### SUMMARY

According to one embodiment of the present disclosure, a substrate support includes: a base electrically connected to at least one power supply; a first dielectric disposed on the base and having a substrate support surface; and a second dielectric disposed on the base to surround the first dielectric and having a ring support surface. The first dielectric includes therein: a first heat transfer gas diffusion space configured to supply a heat transfer gas toward the substrate support surface; a first electrode disposed above the first heat transfer gas diffusion space to vertically overlap with at least a part of the first heat transfer gas diffusion space; and a conductor that electrically connects the first electrode and the base. The second dielectric includes therein: a second heat transfer gas diffusion space configured to supply a heat transfer gas toward the ring support surface; and a second electrode disposed above the second heat transfer gas diffusion space to vertically overlap with at least a part of the second heat transfer gas diffusion space, and electrically connected to a power supply that outputs a common voltage with the base.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a configuration example of a plasma processing system.

FIG. 2 is a block diagram of a computer that can implement various embodiments.

FIG. 3 is a view for explaining a configuration example of a capacitively coupled plasma processing apparatus.

FIG. 4 is a cross-sectional view illustrating a schematic configuration of a substrate support according to an embodiment.

FIG. 5 is an explanatory view of capacitance in a substrate support with a conventional structure.

FIG. 6 is an explanatory view of capacitance in the substrate support according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of semiconductor devices, a variety of plasma processing such as etching, film formation, and diffusion is performed on a semiconductor substrate (hereinafter simply referred to as “substrate”) supported by a substrate support inside a chamber. In the plasma processing described above, it is important to control a temperature of the substrate appropriately during the processing, in order to obtain processing results with high in-plane uniformity with respect to the substrate as a processing target.

The temperature of the substrate during the plasma processing is controlled by, for example, forming a gas supply space inside the substrate support that supports the substrate as the processing target and supplying a heat transfer gas between a back surface of the substrate and a substrate support surface.

However, in the case of forming the gas supply space inside the substrate support as described above, a difference in potential is generated inside the gas supply space when radio frequency power is applied to the substrate support during the plasma processing. As a result, there is a concern that abnormal discharge may occur in the gas supply space.

The technique of the present disclosure has been developed in consideration of the above-described circumstances, and prevents occurrence of abnormal discharge in a gas diffusion space formed inside a substrate support during plasma-processing a substrate. Hereinafter, a substrate processing apparatus and substrate support according to the present embodiment will be described with reference to the drawings. In addition, in this specification and the accompanying drawings, elements having substantially the same functional configuration will be denoted by the same reference numerals, and redundant explanations thereof will be omitted.

### <Plasma Processing System>

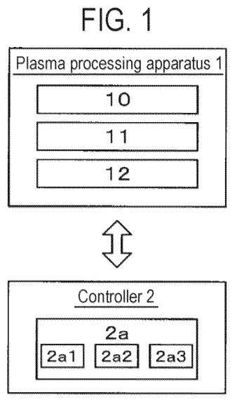

First, a plasma processing system according to one embodiment will be described with reference to FIG. 1. FIG. 1 is a view illustrating a configuration example of a plasma processing system.

In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas discharge port for discharging a gas from the plasma processing space. The gas supply port is connected to a gas supply 20 to be described later, and the gas discharge port is connected to an exhaust system 40 to be described later. The substrate support 11 is disposed inside the plasma processing space, and has a substrate support surface for supporting a substrate and a ring support surface for supporting an edge ring.

The plasma generator 12 is configured to generate plasma from the at least one processing gas supplied into the plasma processing space. The plasma generated in the plasma processing space may be a capacitively coupled plasma (CCP), inductively coupled plasma (ICP), electron-cyclotron-resonance (ECR) plasma, helicon wave excitation plasma (HWP), surface wave plasma (SWP), or the like. Further, various types of plasma generators, including an alternating current (AC) plasma generator and a direct current (DC) plasma generator, may be used. In one embodiment, AC signals (AC power) used in the AC plasma generator have a frequency within a range of 100 kHz to 10 GHz. Thus, the AC signals include radio frequency (RF) signals and microwave signals. In one embodiment, the RF signals have a frequency within a range of 100 kHz to 150 MHz.

The controller 2 processes computer-executable instructions that cause the plasma processing apparatus 1 to execute various processes described in the present disclosure. The controller 2 may be configured to control individual components of the plasma processing apparatus 1 so as to execute various processes described herein. In one embodiment, a part or all of the controller 2 may be included in the plasma processing apparatus 1. The controller 2 may include a processor 2al, a storage 2a2, and a communication interface 2a3. The controller 2 is implemented by, for example, a computer 2a. The processor 2al may be configured to perform various control operations by reading a program from the storage 2a2 and executing the read program. The program may be stored in advance in the storage 2a2, or may be acquired via a medium when necessary. The acquired program is stored in the storage 2a2, and is read from the storage 2a2 and executed by the processor 2al. The medium may be any of various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may perform communication with the plasma processing apparatus 1 via a communication line such as a local area network (LAN). Further, the storage medium may be transitory or non-transitory.

### <Controller or Control Circuit>

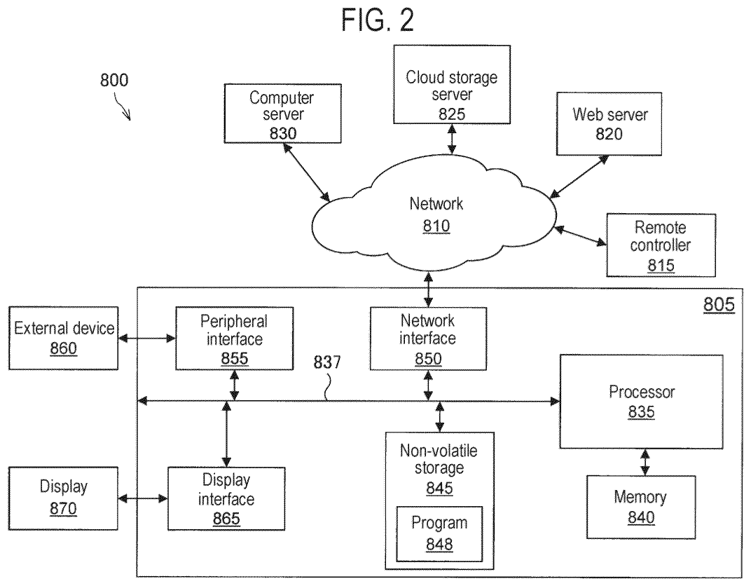

FIG. 2 is a block diagram of a computer that can implement various embodiments described in this specification. Control modes of the present disclosure may be embodied as a system, method, and/or computer program product. The computer program product may include a non-transitory computer-readable storage medium with computer-readable program instructions recorded thereon and one or more processors may execute aspects of the embodiments.

The computer-readable storage medium may be a tangible device capable of storing instructions for use by an instruction execution device (processor). Examples of the computer-readable storage medium may include, but are not limited to, an electronic storage device, a magnetic storage device, an optical storage device, an electromagnetic storage device, a semiconductor memory device, or any appropriate combination of these devices. A non-exhaustive list of more specific examples of the computer-readable storage medium (and appropriate combinations) may include each of the following: a flexible disk, a hard disk, a solid-state drive (SSD), a random access memory (RAM), a read-only memory (ROM), a programmable read-only memory (EPROM or flash), a static random access memory (SRAM), a compact disk (CD or CD-ROM), a digital versatile disk (DVD), and a memory card or stick. The computer-readable storage medium used in the present disclosure is not to be construed as being transitory signals itself, such as radio waves or other electromagnetic waves that freely propagate, electromagnetic waves that propagate via waveguides or other transmission media (e.g., optical pulses passing through optical fiber cables), or electrical signals passing through electrical wires.

The computer-readable program instructions described in present disclosure may be downloaded to a computing device or processing device suitable for an external computer or external storage device from the computer-readable storage medium or via a global network (i.e., the Internet), local area network, wide area network, and/or wireless network. The network may include copper wires, optical communication fibers, wireless transmission, routers, firewalls, switches, gateway computers, and edge servers. A network adapter card or network interface of each computing device or processing device may receive computer-readable program instructions from the network, and may transmit the computer-readable program instructions to store the computer-readable program instructions in the computer-readable storage medium in the computing device or processing device.

The computer-readable program instructions for executing operations of the present disclosure may include machine language instructions and/or microcode, and may be compiled or interpreted from source code written in any combination of one or more programming languages such as assembly language, Basic, Fortran, Java, Python, R, C, C++, C#, and similar programming languages. The computer-readable program instructions may be executed entirely on a user's personal computer, laptop computer, tablet, or smartphone, or may be executed entirely on a remote computer or computer server, or on any combination of these computing devices. The remote computer or computer server may be connected to a user's device or devices via a computer network including a local area network, wide area network, or global network (the Internet). In some embodiments, an electronic circuit may include a programmable logic circuit, field programmable gate array (FPGA), or programmable logic array (PLA), for example, and aspects of the present disclosure may be implemented by configuring or customizing the electronic circuit by executing computer-readable program instructions using information from the computer-readable program instructions.

Aspects of the present disclosure will be described with reference to flowcharts and block diagrams of a method according to the embodiments of the disclosure, an apparatus (system), and a computer program product. It is understood by those skilled in the art that each block in the flowcharts and block diagrams and combinations of blocks in the flowcharts and block diagrams may be implemented by computer-readable program instructions.

The computer-readable program instructions capable of implementing the system and method described in the present disclosure may be provided to one or more processors (and/or one or more cores within the processors) of a general-purpose computer, a special-purpose computer, or another programmable device. These computer-readable program instructions may be stored in a computer-readable storage medium capable of instructing a computer, a programmable device, and/or another device to function in a particular manner. In such a case, the computer-readable storage medium storing the instructions is a product containing instructions that implement aspects of functions specified in the flowcharts and block diagrams of the present disclosure.

Further, the computer-readable program instructions may be loaded into a computer, another programmable device, or another device, and the instructions executed on the computer, other programmable device, or other device may execute a series of operational steps to generate a computer-implemented process that implements function specified in the flowcharts and block diagrams of the present disclosure.

FIG. 2 is a functional block diagram illustrating a networked system 800 including a plurality of networked computers and servers. In one embodiment, hardware and software environment illustrated in FIG. 2 may provide an exemplary platform for implementing software and/or a method according to the present disclosure.

As illustrated in FIG. 2, the networked system 800 may include a computer 805, a network 810, a remote computer 815, a web server 820, a cloud storage server 825, and a computer server 830, but the networked system 800 is not limited thereto. In some embodiments, a plurality of instances of one or more functional blocks illustrated in FIG. 2 may be employed.

Additional details of the computer 805 are illustrated in FIG. 2. The functional blocks illustrated in the computer 805 are provided only to establish exemplary functions and are not intended to be exhaustive. Further, while details of the remote computer 815, the web server 820, the cloud storage server 825, and the computer server 830 are not provided, these other computers and devices may have functions similar to those illustrated for the computer 805.

The computer 805 may be a personal computer (PC), a desktop computer, a laptop computer, a tablet computer, a netbook computer, a personal digital assistant (PDA), a smartphone, or any other programmable electronic device that may communicate with other devices on the network 810.

The computer 805 may include a processor 835, a bus 837, a memory 840, a non-volatile storage 845, a network interface 850, a peripheral interface 855, and a display interface 865. In some embodiments, each of these functions may be implemented as an individual electronic subsystem (combinations of integrated circuit chips or devices associated with the chips). Alternatively, in other embodiments, some combinations of functions may be implemented on a single chip (sometimes referred to as a chip-on-system or SoC).

The processor 835 may be one or a plurality of single-chip or multi-chip microprocessors such as those designed and/or manufactured by Intel Corporation, Advanced Micro Devices (AMD), Arm Holdings (ARM), Apple Computer, and the like. Examples of the microprocessors include Intel's Celeron, Pentium, Core i3, Core i5, and Core i7, AMD's Opteron, Phenom, Athlon, Turion, and Ryzen, and Arm's Cortex-A, Cortex-R, and Cortex-M.

The bus 837 may be a high-speed parallel or serial peripheral interconnect bus of an independent standard, such as ISA, PCI, PCI Express (PCI-e), or AGP.

The memory 840 and the non-volatile storage 845 may be computer-readable storage media. The memory 840 may include any appropriate volatile storage device, such as dynamic random access memory (DRAM) or static random access memory (SRAM). The non-volatile storage 845 may include one or more of a flexible disk, a hard disk, a solid-state drive (SSD), a read-only memory (ROM), a programmable read-only memory (EPROM or Flash), a compact disk (CD or CD-ROM), a digital versatile disk, and a memory card or stick.

A program 848 is stored in the non-volatile storage 845, and may be a set of machine-readable instructions and/or data that are used to create, manage, and control specific software functions, which are described in detail elsewhere in the present disclosure and are also illustrated in the drawings. In some embodiments, the memory 840 may be significantly faster than the non-volatile storage 845. In such embodiments, the program 848 may be transmitted from the non-volatile storage 845 to the memory 840 before being executed by the processor 835.

The computer 805 may communicate and interact with other computers over the network 810 via the network interface 850. The network 810 may include, for example, a local area network (LAN), a wide area network (WAN) such as the Internet, or a combination of both, and may include wired, wireless, or optical fiber connection. In general, the network 810 may be any combination of connections and protocols that support communication between two or more computers and associated devices.

The peripheral interface 855 may allow an input and output of data with respect to other devices that may be locally connected to the computer 805. For example, the peripheral interface 855 may provide a connection to an external device 860. The external device 860 may include devices such as a keyboard, a mouse, a keypad, a touch screen, and/or other appropriate input devices. The external device 860 may also include a portable computer-readable storage medium, such as a thumb drive, a portable optical or magnetic disk, or a memory card. Software and data used in the embodiments of the present disclosure may be stored in, for example, the program 848, a portable computer-readable storage medium, and the like. In such embodiments, the software may be loaded into the non-volatile storage 845 or, alternatively, directly into the memory 840 via the peripheral interface 855. The peripheral interface 855 may be connected to the external device 860 using industry standard connections such as RS-232 or universal serial bus (USB).

The display interface 865 may connect the computer 805 to a display 870. The display 870 may be used to present a command line or graphical user interface to a user of the computer 805 in some embodiments. The display interface 865 may be connected to the display 870 using one or more proprietary connections or industry standard connections such as VGA, DVI, Display Port, HDMI (registered trademark), and the like.

As described above, the network interface 850 provides communication with other computing systems and storage systems or devices external to the computer 805. The software programs and data described in this specification may be downloaded, for example, from the remote computer 815, the web server 820, the cloud storage server 825, and the computer server 830 to the non-volatile storage 845 via the network interface 850 and the network 810.

Furthermore, the system and method described in the present disclosure may be executed by one or more computers connected to the computer 805 via the network interface 850 and the network 810. For example, in some embodiments, the system and method described in the present disclosure may be executed by the remote computer 815, the computer server 830, or a combination of interconnected computers on the network 810.

The data, dataset, and/or database used in the embodiments for implementing the system and method described in the present disclosure may be stored or downloaded from the remote computer 815, the web server 820, the cloud storage server 825, and the computer servers 830.

### <Plasma Processing Apparatus>

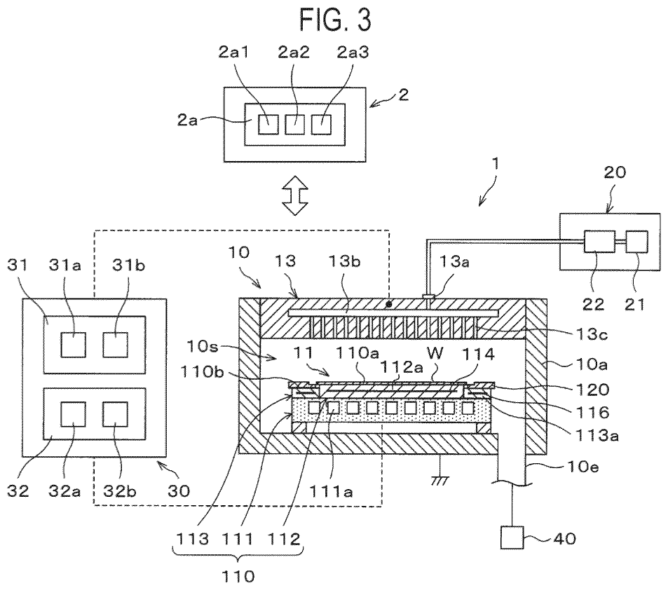

Next, a configuration example of a capacitively coupled plasma processing apparatus will be described as an example of the above-described plasma processing apparatus 1. FIG. 3 is a view illustrating a configuration example of the plasma processing apparatus 1.

The plasma processing apparatus 1 includes the plasma processing chamber 10, the gas supply 20, a power supply 30, and the exhaust system 40. Further, the plasma processing apparatus 1 includes the substrate support 11, which is an example of the substrate support, and a gas introducer. The substrate support 11 is disposed inside the plasma processing chamber 10.

The gas introducer is configured to introduce at least one processing gas into the plasma processing chamber 10. The gas introducer includes a shower head 13. The shower head 13 is located above the substrate support 11. In one embodiment, the shower head 13 constitutes at least a portion of a ceiling of the plasma processing chamber 10. An interior of the plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 110 and a ring assembly 120. The main body 110 has a central region 110a for supporting a substrate W and an annular region 110b for supporting the ring assembly 120. A wafer is an example of the substrate W. The annular region 110b of the main body 110 surrounds the central region 110a of the main body 110 in a plan view. The substrate W is disposed on the central region 110a of the main body 110, and the ring assembly 120 is disposed on the annular region 110b of the main body 110 so as to surround the substrate W on the central region 110a of the main body 110. Thus, the central region 110a is also referred to as a substrate support surface for supporting the substrate W, and the annular region 110b is also referred to as a ring support surface for supporting the ring assembly 120.

Further, in one embodiment, the main body 110 includes a conductive base 111, an electrostatic chuck 112, and an annular electrostatic chuck 113.

The conductive base 111 includes a conductive member such as aluminum and has a substantially disk shape. The conductive member of the conductive base 111 may function as a lower electrode.

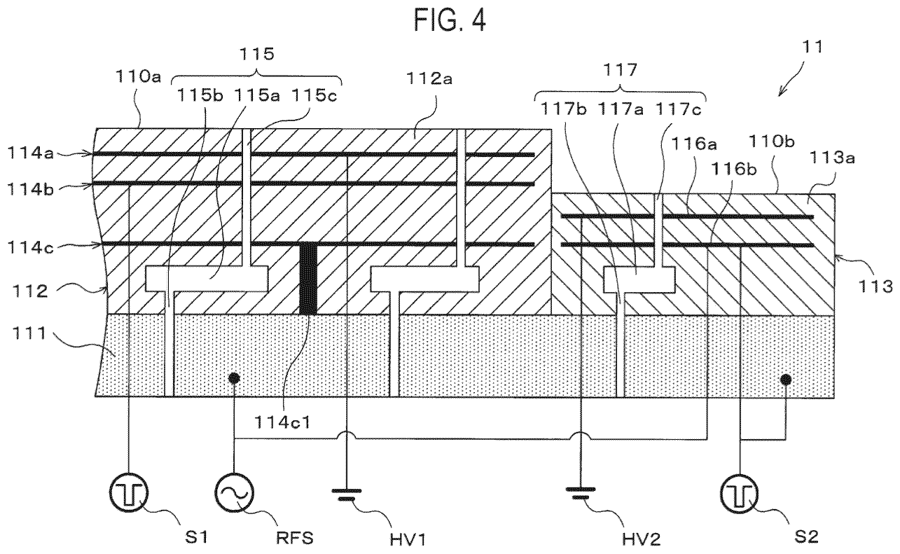

The electrostatic chuck 112 is disposed on the conductive base 111. The electrostatic chuck 112 includes a ceramic member 112a, a plurality of electrodes 114 disposed inside the ceramic member 112a, and a heat transfer gas supply 115 formed inside the ceramic member 112a (see FIG. 4). The ceramic member 112a has the central region 110a.

The annular electrostatic chuck 113 is disposed on the conductive base 111 to surround the electrostatic chuck 112. The annular electrostatic chuck 113 includes a ceramic member 113a, a plurality of electrodes 116 disposed inside the ceramic member 113a, and a heat transfer gas supply 117 formed inside the ceramic member 113a (see FIG. 4). The ceramic member 113a has the annular region 110b. The annular electrostatic chuck 113 may be formed integrally with the electrostatic chuck 112 on the conductive base 111 as illustrated, or may be formed independently (separately).

At least one RF/DC electrode, which is coupled to an RF power supply 31 and/or DC a power supply 32 to be described later, may be disposed inside the ceramic members 112a and 113a. The at least one RF/DC electrode may correspond to the plurality of electrodes 114 and the plurality of electrodes 116 described above. In this case, the at least one RF/DC electrode functions as a lower electrode. When a bias RF signal and/or DC signal to be described later is supplied to the at least one RF/DC electrode, the RF/DC electrode is also referred to as a bias electrode. In addition, the conductive member of the conductive base 111 and the at least one RF/DC electrode may function as a plurality of lower electrodes. Further, an electrostatic electrode may function as a lower electrode. Thus, the substrate support 11 includes at least one lower electrode.

The ring assembly 120 includes one or a plurality of annular members. In one embodiment, the one or plurality of annular members includes one or a plurality of edge rings. Further, the one or plurality of annular members may include at least one covering. The edge ring is made of a conductive material or insulating material, and the covering is made of an insulating material.

The ring assembly 120 may be disposed on the annular electrostatic chuck 113, or may be disposed on both the electrostatic chuck 112 and the annular electrostatic chuck 113.

Further, the substrate support 11 may include a temperature regulation module configured to regulate at least one of the electrostatic chuck 112, the annular electrostatic chuck 113, the ring assembly 120, or the substrate W to be a target temperature. The temperature regulation module may include a heater, a heat transfer medium, a flow path 111a, or a combination thereof. The heat transfer fluid such as brine or a gas flows through the flow path 111a. In one embodiment, the flow path 111a is formed inside the conductive base 111, and one or a plurality of heaters is disposed inside the ceramic member 112a of the electrostatic chuck 112 and the ceramic member 113a of the annular electrostatic chuck 113. In addition, the temperature regulation module is not limited to the configuration described above, and may have any other configuration as long as it may adjust the temperature of at least one of the electrostatic chuck 112, the annular electrostatic chuck 113, the ring assembly 120, or the substrate W.

In addition, a detailed configuration of the substrate support 11 will be described later.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b, and is introduced into the plasma processing space 10s from the gas introduction ports 13c. Further, the shower head 13 includes at least one upper electrode. In addition to the shower head 13, the gas introducer may include one or a plurality of side gas injectors (SGIs) provided in one or a plurality of openings formed in the sidewall 10a.

The gas supply 20 may include at least one gas source 21 and at least one flow rate controller 22. In one embodiment, the gas supply 20 is configured to supply at least one processing gas from a corresponding gas source 21 to the shower head 13 via a corresponding flow rate controller 22. Each flow rate controller 22 may include, for example, a mass flow rate controller or a pressure-controlled flow rate controller. Further, the gas supply 20 may include at least one flow rate modulation device that modulates or pulses a flow rate of the at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. With this configuration, plasma is generated from the at least one processing gas supplied to the plasma processing space 10s. Thus, the RF power supply 31 may function as at least a part of the plasma generator 12. Further, when the bias RF signal is supplied to at least one lower electrode, a bias potential is generated in the substrate W, thereby causing ions of the generated plasma to be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals with different frequencies. The generated one or the plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). A frequency of the bias RF signal may be the same as or different from the frequency of the source RF signal. In one embodiment, the bias RF signal has a lower frequency than that of the source RF signal. In one embodiment, the bias RF signal has a frequency within a range of 100 kHz to 60 MHz. In one embodiment, the second RF generator 31b may be configured to generate a plurality of bias RF signals with different frequencies. The generated one or the plurality of bias RF signals is supplied to at least one lower electrode. Further, in various embodiments, at least one of the source RF signal or the bias RF signal may be pulsed.

Further, the power supply 30 may include the DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may have a rectangular, trapezoidal, or triangular pulse waveform, or a combination thereof. In one embodiment, a waveform generator configured to generate the voltage pulse sequence from DC signals is connected between the first DC generator 32a and at least one lower electrode. Thus, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Further, the voltage pulse sequence may include one or a plurality of positive-polarity voltage pulses or one or a plurality of negative-polarity voltage pulses within one cycle. In addition, the first and second DC generators 32a and 32b may be provided in addition to the RF power supply 31, and the first DC generator 32a may be provided in place of the second RF generator 31b.

The exhaust system 40 may be connected, for example, to a gas outlet 10e provided in a bottom of the plasma processing chamber 10. The exhaust system 40 may include a pressure adjustment valve and a vacuum pump. An internal pressure of the plasma processing space 10s is adjusted by the pressure adjustment valve. The vacuum pump may include a turbomolecular pump, a dry pump, or a combination thereof.

### <Substrate Support>

Next, details of an example configuration of the substrate support 11 serving as the substrate support according to the present embodiment will be described. FIG. 4 is a cross-sectional view illustrating a schematic configuration of the substrate support 11. In addition, in FIG. 4, illustrations of the substrate W supported by the electrostatic chuck 112, the ring assembly 120 supported by the annular electrostatic chuck 113, and the flow path 111a inside the conductive base 111 are omitted.

As described above, the substrate support 11 includes the main body 110 and the ring assembly 120. The main body 110 includes the conductive base 111, the electrostatic chuck 112, and the annular electrostatic chuck 113.

The conductive base 111 includes the conductive member such as aluminum and has a substantially disk shape. The electrostatic chuck 112 and the annular electrostatic chuck 113 are disposed on the conductive base 111. In one example, the electrostatic chuck 112 and the annular electrostatic chuck 113 are bonded onto the conductive base 111 via a bonding layer (not illustrated). The bonding layer is made of a plasma-resistant and heat-resistant material, such as an acrylic resin, a silicon resin, or an epoxy resin.

As illustrated in FIG. 4, a radio frequency power supply RFS that generates the source RF signal and a bias power supply S2 that generates a bias signal for the ring assembly 120 as described later are electrically connected to the conductive base 111. The power supply 30 described above may be used as the radio frequency power supply RFS.

The electrostatic chuck 112 is disposed on the conductive base 111, as described above. The electrostatic chuck 112 includes the ceramic member 112a having at least one layer of an insulating (dielectric) member, for example, a ceramic layer in the present embodiment. The ceramic member 112a has the central region 110a on an upper surface thereof.

The annular electrostatic chuck 113 is disposed on the conductive base 111 to surround the electrostatic chuck 112, as described above. The annular electrostatic chuck 113 includes the ceramic member 113a having at least one layer of an insulating (dielectric) member, for example, a ceramic layer in the present embodiment. The ceramic member 113a has the annular region 110b on an upper surface thereof.

The ceramic member 112a of the electrostatic chuck 112 has a larger thickness than the ceramic member 113a of the annular electrostatic chuck 113. In other words, the main body 110 of the substrate support 11 has a substantially convex cross-sectional shape with the substrate support surface (central region 110a) higher than the ring support surface (annular region 110b) such that a convex portion is formed on an upper surface thereof.

The plurality of electrodes 114, which includes an electrostatic electrode 114a, a bias electrode 114b, and a discharge prevention electrode 114c, is provided inside the ceramic member 112a, which is a first dielectric. The electrostatic electrode may be an example of a clamp electrode. Further, the heat transfer gas supply 115 is formed inside the ceramic member 112a to supply a gas for heat transfer such as helium gas (hereinafter referred to as “heat transfer gas”) between a back surface of the substrate W and the central region 110a. The electrostatic chuck 112 is configured by sandwiching the electrostatic electrode 114a, the bias electrode 114b, the discharge prevention electrode 114c, and heat transfer gas supply 115 inside the ceramic member 112a (e.g., between a pair of dielectric films made of a non-magnetic dielectric material such as ceramics).

An electrostatic attraction power supply HV1 for the substrate W is electrically connected to the electrostatic electrode 114a. Further, by applying a voltage to the electrostatic electrode 114a from the electrostatic attraction power supply HV1, an electrostatic force such as Coulomb force is generated, and the substrate W is attracted to and held by the central region 110a by the generated electrostatic force. The power supply 30 described above may be used as the electrostatic attraction power supply HV1.

In addition, a positive voltage or a negative voltage may be output from the electrostatic attraction power supply HV1. The electrostatic attraction power supply HV1 may be a DC power supply or an AC power supply. Further, the electrostatic electrode 114a may be monopolar or multipolar. Furthermore, the electrostatic electrode 114a may be divided.

The bias electrode 114b is located below the electrostatic electrode 114a inside the ceramic member 112a. The bias electrode 114b is mainly used to draw ions to a central portion of the substrate W. The bias electrode 114b may also function as a lower electrode. A bias power supply S1 for the substrate W is electrically connected to the bias electrode 114b. The bias power supply S1 outputs a negative DC pulse in one example. The power supply 30 described above may be used as the bias power supply S1.

In addition, a voltage applied from the bias power supply S1 is not limited to the negative DC pulse and may be changed appropriately according to the purpose of substrate processing in the plasma processing apparatus 1. That is, a positive voltage may be applied in place of the negative voltage, and a radio frequency AC voltage may be applied in place of the DC voltage. Further, continuous waves may be supplied in place of the pulse waves. Furthermore, the bias electrode 114b may be divided.

The discharge prevention electrode 114c is disposed inside the ceramic member 112a below the bias electrode 114b and above a diffusion space 115a of the heat transfer gas supply 115 to be described later. Further, the discharge prevention electrode 114c is disposed to overlap with at least a part of the diffusion space 115a to be described later when viewed in a vertical direction (in a plan view), and may be disposed to overlap with an entire surface of the diffusion space 115a in a plan view. The discharge prevention electrode 114c is electrically connected to the conductive base 111 via a conductive member 114c1, and a common voltage with the conductive base 111 is applied to the discharge prevention electrode 114c. Thus, an equipotential space is formed inside the ceramic member 112a between the conductive base 111 and the discharge prevention electrode 114c in a thickness direction. The conductive member 114c1 corresponds to a “conductor” according to the technique of the present disclosure.

In addition, the number of conductive members 114c1 that connect the conductive base 111 and the discharge prevention electrode 114c is not particularly limited, and a plurality of conductive members 114c1 may be disposed along a circumferential direction of the electrostatic chuck 112. In this case, the conductive members 114c1 may be disposed at equal intervals along the circumferential direction of the electrostatic chuck 112. The conductive members 114c1 may be vias, for example. Further, the discharge prevention electrode 114c may be divided.

The heat transfer gas supply 115 includes the diffusion space 115a, a gas inlet 115b configured to supply the heat transfer gas to the diffusion space 115a, and a gas outlet 115c configured to discharge the heat transfer gas from the diffusion space 115a. The heat transfer gas supply 115 supplies the heat transfer gas from a heat transfer gas source (not illustrated) to a space between the back surface of the substrate W and the central region 110a via the gas inlet 115b, the diffusion space 115a, and the gas outlet 115c in this order. The heat transfer gas is also referred to as “backside gas.”

In addition, a plurality of heat transfer gas supplies 115 may be formed inside the ceramic member 112a. Further, the heat transfer gas supply 115 may be formed by burying a gas supply pipe inside the ceramic member 112a, or may be formed as a cavity by not stacking ceramics (dielectric members) at a portion inside the ceramic member 112a.

The diffusion space 115a, which a first heat transfer gas diffusion space, is formed below the discharge prevention electrode 114c inside the ceramic member 112a. More specifically, the diffusion space 115a is formed inside the ceramic member 112a between the conductive base 111 and the discharge prevention electrode 114c, i.e., in the above-described equipotential space.

The gas inlet 115b is formed to extend downward from the diffusion space 115a to a lower surface of the conductive base 111. A heat transfer gas source (not illustrated) is connected to the gas inlet 115b.

The gas outlet 115c is formed to extend upward from the diffusion space 115a to the substrate support surface (central region 110a), which is an upper surface of the ceramic member 112a. The number of gas outlets 115c extending from the diffusion space 115a, in other words, the number of heat transfer gas discharge holes on the substrate support surface, is not particularly limited, and a plurality of gas outlets 115c may be formed along the circumferential direction of the electrostatic chuck 112.

As described above, in the substrate support 11 according to the present embodiment, the diffusion space 115a configured to supply the heat transfer gas is formed in the equipotential space inside the ceramic member 112a. Therefore, generation of a potential difference inside the diffusion space 115a may be suppressed, thereby suppressing generation of abnormal discharge in the diffusion space 115a during plasma processing of the substrate W.

As the plurality of electrodes 116, an electrostatic electrode 116a and a bias electrode 116b are provided inside the ceramic member 113a, which is a second dielectric. Further, the heat transfer gas supply 117 configured to supply the heat transfer gas is formed inside the ceramic member 113a between a back surface of the ring assembly 120 and the annular region 110b. The annular electrostatic chuck 113 is configured by sandwiching the electrostatic electrode 116a, the bias electrode 116b and the heat transfer gas supply 117 inside the ceramic member 113a (e.g., between a pair of dielectric films made of a non-magnetic dielectric material such as ceramics).

An electrostatic attraction power supply HV2 for the ring assembly 120 is electrically connected to the electrostatic electrode 116a. Further, by applying a voltage to the electrostatic electrode 116a from the electrostatic attraction power supply HV2, an electrostatic force such as Coulomb force is generated, and the ring assembly 120 is attracted to and held by the annular region 110b by the generated electrostatic force. The power supply 30 described above may be used as the electrostatic attraction power supply HV2.

In addition, a positive voltage or a negative voltage may be output from the electrostatic attraction power supply HV2. The electrostatic attraction power supply HV2 may be a DC power supply or an AC power supply. Further, the electrostatic electrode 116a may be monopolar or multipolar. Furthermore, the electrostatic electrode 116a may be divided.

The bias electrode 116b is disposed below the electrostatic electrode 116a inside the ceramic member 113a. Further, the bias electrode 116b is disposed to overlap with at least a part of a diffusion space 117a to be described later when viewed in the vertical direction (in a plan view), or may be disposed to overlap with an entire surface of the diffusion space 117a in a plan view. The bias electrode 116b is mainly used to draw ions to a peripheral edge of the substrate W. The bias power supply S2 for the ring assembly 120 and the above-described radio frequency power supply RFS are electrically connected to the bias electrode 116b. In other words, a power supply connected to the bias electrode 116b is the same to that connected to the conductive base 111. With this configuration, in the ceramic member 113a, a common voltage is applied to the conductive base 111 and the bias electrode 116b, thereby forming an equipotential space between the conductive base 111 and the bias electrode 116b in the thickness direction. The power supply 30 described above may be used as the bias power supply S2.

In addition, the bias power supply S2 may output a negative DC pulse in one example, but a voltage applied from the bias power supply S2 may be appropriately changed according to the purpose of substrate processing in the plasma processing apparatus 1. That is, a positive voltage may be applied in place of the negative voltage, and a radio frequency AC voltage may be applied in place of the DC voltage. Further, continuous waves may be supplied in place of the pulse waves. Furthermore, the bias electrode 116b may be divided.

The heat transfer gas supply 117 includes the diffusion space 117a, a gas inlet 117b configured to supply the heat transfer gas to the diffusion space 117a, and a gas outlet 117c configured to discharge the heat transfer gas from the diffusion space 117a. The heat transfer gas supply 117 supplies the heat transfer gas from a heat transfer gas source (not illustrated) to a space between the back surface of ring assembly 120 and the annular region 110b via the gas inlet 117b, the diffusion space 117a, and the gas outlet 117c in this order.

In addition, a plurality of heat transfer gas supplies 117 may be formed inside the ceramic member 113a. Further, the heat transfer gas supply 117 may be formed by burying a gas supply pipe inside the ceramic member 113a, or may be formed as a cavity by not stacking ceramics (dielectric member) at a portion inside the ceramic member 113a.

The diffusion space 117a, which a second heat transfer gas diffusion space, is formed below the bias electrode 116b inside the ceramic member 113a. More specifically, the diffusion space 117a is formed inside the ceramic member 113a between the conductive base 111 and the bias electrode 116b, i.e., in the above-described equipotential space.

The gas inlet 117b is formed to extend downward from the diffusion space 117a to the lower surface of the conductive base 111. A heat transfer gas source (not illustrate) is connected to the gas inlet 117b. In addition, the heat transfer gas source connected to the gas inlet 117b may be used in common with the heat transfer gas source connected to the heat transfer gas supply 115 on a side of the electrostatic chuck 112, or may be used independently. In other words, the plasma processing apparatus 1 according to the present embodiment is provided with one or a plurality of heat transfer gas sources (not illustrated).

The gas outlet 117c is formed to extend upward from the diffusion space 117a to the ring support surface (annular region 110b), which is an upper surface of the ceramic member 113a. The number of gas outlets 117c extending from the diffusion space 117a, in other words, the number of heat transfer gas discharge holes on the ring support surface, is not particularly limited, and a plurality of gas outlets 117c may be formed along a circumferential direction of the annular electrostatic chuck 113.

As described above, in the substrate support 11 according to the present embodiment, the diffusion space 117a configured to supply the heat transfer gas is formed in the equipotential space inside the ceramic member 113a. Therefore, generation of a potential difference inside the diffusion space 117a may be suppressed, thereby suppressing generation of abnormal discharge in the diffusion space 117a during plasma processing of the substrate W.

According to the substrate support 11 of the present embodiment as described above, the discharge prevention electrode 114c electrically connected to the conductive base 111 is disposed in the electrostatic chuck 112, thereby forming the equipotential space inside the ceramic member 112a. Further, in the annular electrostatic chuck 113, the common power supply is connected to both the bias electrode 116b and the conductive base 111 to apply the common voltage thereto, thereby forming the equipotential space inside the ceramic member 113a.

Further, in the substrate support 11 according to the present embodiment, the diffusion spaces 115a and 117a configured to supply the heat transfer gas between the back surface of the substrate W and the central region 110a and between the back surface of the ring assembly 120 and the annular region 110b, respectively, are disposed in the equipotential spaces formed inside the ceramic members 112a and 113a.

By disposing the diffusion spaces 115a and 117a in the equipotential spaces as described above, generation of potential differences in the diffusion spaces 115a and 117a is suppressed. As a result, it is possible to suppress generation of abnormal discharge in the diffusion spaces 115a and 117a during plasma processing of the substrate W.

In addition, in the above-described embodiment, the discharge prevention electrode 114c electrically connected to the conductive base 111 is disposed in the electrostatic chuck 112 on a side of the central region 110a, and the bias electrode 116b disposed in the annular electrostatic chuck 113 on a side of the annular region 110b is connected to a common power supply with the conductive base 111, but forming the respective equipotential spaces is not limited thereto.

In other words, for example, discharge prevention electrodes electrically connected to the conductive base 111 may be disposed in both the electrostatic chuck 112 and the annular electrostatic chuck 113, or bias electrodes may be connected to the common power supply with the conductive base 111 in both the electrostatic chuck 112 and the annular electrostatic chuck 113. Further, for example, the bias electrode 114b may be connected to the common power supply with the conductive base 111 in the electrostatic chuck 112, and a discharge prevention electrode electrically connected to the conductive base 111 may be disposed in the annular electrostatic chuck 113.

In addition, in the above-described embodiment, for example, from the viewpoint of ease of molding the electrostatic chuck, the discharge prevention electrode 114c inside the ceramic member 112a is disposed at the same height position (in the same plane) as the bias electrode 116b inside the ceramic member 113a, but disposing the discharge prevention electrode 114c is not limited thereto.

When the substrate W is placed on the central region 110a, capacitances are generated between the substrate W and the electrostatic electrode 114a, between the electrostatic electrode 114a and the bias electrode 114b, and between the bias electrode 114b and the discharge prevention electrode 114c, and synthesizing these capacitances results in generation of a capacitance between the substrate W and the discharge prevention electrode 114c. Since the capacitance depends on a distance between the substrate W and the discharge prevention electrode 114c, a value of the capacitance generated between the substrate W and the discharge prevention electrode 114c can be adjusted by changing the height position of the discharge prevention electrode 114c inside the ceramic member 112a. Thus, by changing the height position of the discharge prevention electrode 114c inside the ceramic member 112a, it is possible to control a capacitance ratio between the electrostatic chuck 112 with the substrate W placed thereon and the annular electrostatic chuck 113 with the ring assembly 120 placed thereon. In other words, it is possible to control an impedance ratio between the electrostatic chuck 112 with the substrate W placed thereon and the annular electrostatic chuck 113 with the ring assembly 120 placed thereon.

Hereinafter, details of a method of controlling the capacitance ratio between the substrate W and the ring assembly 120, which are placed on the substrate support 11, according to the present embodiment will be described.

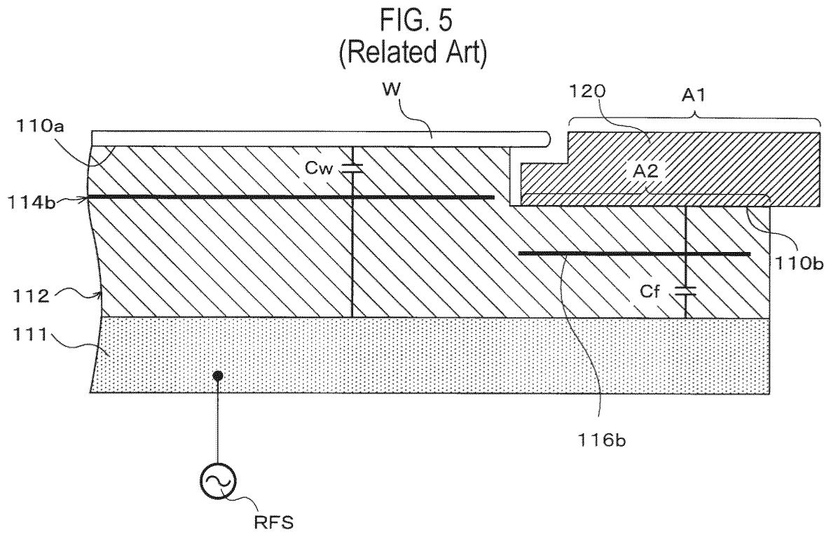

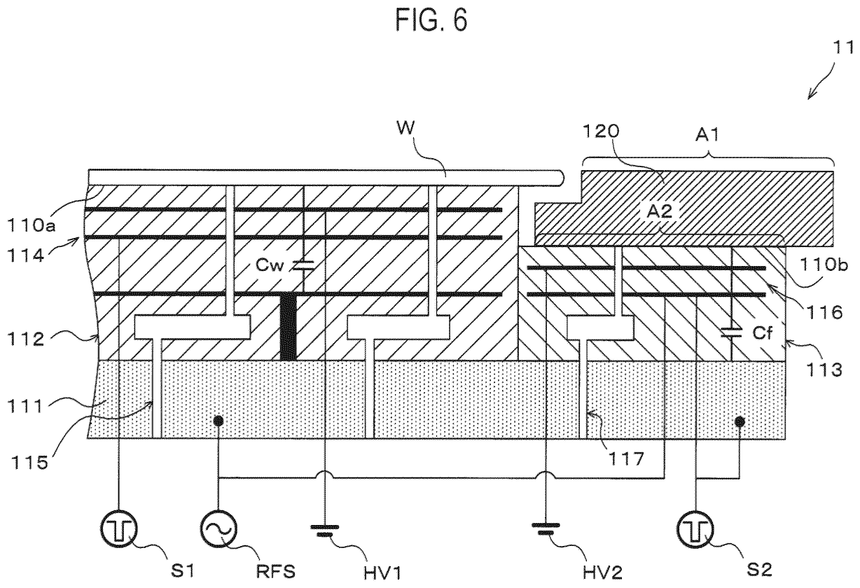

FIGS. 5 and 6 are explanatory views illustrating a capacitance between the substrate W and the ring assembly 120 in the substrate support. FIG. 5 is an explanatory view of a substrate support having a conventional structure in which the discharge prevention electrode 114c is not disposed, whereas FIG. 6 is an explanatory view of the substrate support 11 according to the present embodiment in which the discharge prevention electrode 114c is disposed. In addition, in the substrate support having the conventional structure illustrated in FIG. 5, elements having substantially the same functional configuration as the substrate support 11 according to the present embodiment illustrated in FIG. 6 are denoted by the same reference numerals and detailed descriptions thereof will be omitted.

In order to improve in-plane uniformity of plasma processing on the substrate W, it is important to uniformly apply the radio frequency power (RF), which is applied to the conductive base 111, to both the substrate W and the ring assembly 120 (edge ring), thereby uniformly drawing ions to the entire surface of the substrate W.

However, since the radio frequency power applied to the conductive base 111 is applied to the substrate W and the ring assembly 120 via the dielectric ceramic members 112a and 113a, respectively, it may lead to a distribution in a ratio of the radio frequency power applied to the substrate W and the ring assembly 120, i.e. an impedance ratio between the substrate W and the ring assembly 120.

Specifically, an impedance of the substrate W is determined by a reciprocal of a capacitance Cw. The parasitic capacitance Cw of the substrate W may depend on, for example, a thickness of a dielectric (ceramic member 112a) via which the radio frequency power is transmitted, i.e., a distance between the conductive base 111 and the substrate W.

Further, an impedance of the ring assembly 120 is determined by a reciprocal of a capacitance [Cf×A1/A2]. The parasitic capacitance Cf of the ring assembly 120 (see FIG. 5) may depend on, for example, a thickness of a dielectric (ceramic member 113a) via which the radio frequency power is transmitted, i.e., a distance between the conductive base 111 and the ring assembly 120. Further, the aforementioned area A1 (see FIG. 5) is an exposed area of the ring assembly 120 to the plasma processing space, i.e., an area of an upper surface of the ring assembly 120. The aforementioned area A2 (see FIG. 5) is an area of an input side of the radio frequency power to the ring assembly 120, i.e., a contact area between the ring assembly 120 and the annular region 110b.

As described above, the radio frequency power applied from the radio frequency power supply is distributed and propagated according to the impedance of each of the electrostatic chuck 112 with the substrate W placed thereon and the annular electrostatic chuck 113 with the ring assembly 120 placed thereon.

However, in the support having the conventional substrate in which the discharge prevention electrode 114c is not disposed, as illustrated in FIG. 5, there was a case where the impedance (capacitance Cw) of the substrate W and the impedance (capacitance [Cf×A1/A2]) of the ring assembly 120 do not match with each other, resulting in a distribution in capacitance between the substrate W and the ring assembly 120.

In this regard, in the substrate support 11 according to the present embodiment in which the discharge prevention electrode 114c is disposed, it is easy to match the capacitance Cw of the substrate W with the capacitance [Cf×A1/A2] of the ring assembly 120.

In other words, in the substrate support 11 according to the present embodiment, as illustrated in FIG. 6, it is possible to arbitrarily adjust a value of parasitic capacitance Cw of the substrate W by changing the height position of the discharge prevention electrode 114c inside the ceramic member 112a. With this configuration, it is possible to adjust the impedance ratio between the substrate W and the ring assembly 120.

More specifically, it is possible to design the height position of the discharge prevention electrode 114c so as to match the capacitance Cw of the substrate W with the capacitance [Cf×A1/A2] of the ring assembly 120 and to effectively suppress generation of a distribution in capacitance coupling between the substrate W and the ring assembly 120.

With the substrate support 11 according to the present embodiment, as described above, it is possible to suppress abnormal discharge in the diffusion spaces of the heat transfer gas formed inside the electrostatic chucks as illustrated in the above embodiment during plasma processing on the substrate W, and to adjust impedance characteristics of the radio frequency in both a substrate placement region and a ring placement region.

According to the present disclosure, it is possible to suppress generation of abnormal discharge in gas diffusion spaces formed inside a substrate support during plasma processing on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate support comprising:
a base electrically connected to at least one power supply;
a first dielectric disposed on the base and having a substrate support surface; and
a second dielectric disposed on the base to surround the first dielectric and having a ring support surface,
wherein the first dielectric comprises:
a first heat transfer gas diffusion space configured to supply a heat transfer gas toward the substrate support surface;
a first electrode disposed above the first heat transfer gas diffusion space to vertically overlap with at least a part of the first heat transfer gas diffusion space; and
a conductor that electrically connects the first electrode and the base, and wherein the second dielectric comprises:
a second heat transfer gas diffusion space configured to supply a heat transfer gas toward the ring support surface; and
a second electrode disposed above the second heat transfer gas diffusion space to vertically overlap with at least a part of the second heat transfer gas diffusion space, and electrically connected to a power supply that outputs a common voltage with the base.

2. The substrate support of claim 1, wherein the first electrode and the second electrode are disposed in a same plane.

3. The substrate support of claim 2, wherein the first dielectric further includes a bias electrode for substrate disposed above the first electrode.

4. The substrate support of claim 3, wherein the first dielectric further includes an electrostatic electrode for substrate disposed above the first electrode.

5. The substrate support of claim 1, wherein the first electrode and the second electrode are disposed in a same plane.

6. The substrate support of claim 1, wherein the first dielectric further includes a bias electrode for substrate disposed above the first electrode.

7. The substrate support of claim 1, wherein the second dielectric further includes an electrostatic electrode for ring disposed above the second electrode.

8. The substrate support of claim 1, wherein the second electrode is a bias electrode for a ring that is supported by the ring support surface.

9. The substrate support of claim 1, wherein a plurality of conductors is disposed along a circumferential direction of the first dielectric.

10. The substrate support of claim 9, wherein the plurality of conductors is disposed at equal intervals along the circumferential direction of the first dielectric.

11. A plasma processing apparatus comprising:
a plasma processing chamber; and
a substrate support disposed inside the plasma processing chamber,
wherein the substrate support comprises:
a base electrically connected to at least one power supply;
a first dielectric disposed on the base and having a substrate support surface; and
a second dielectric disposed on the base to surround the first dielectric part and having a ring support surface,
wherein the first dielectric comprises:
a first heat transfer gas diffusion space configured to supply a heat transfer gas toward the substrate support surface;
a first electrode disposed above the first heat transfer gas diffusion space; and
a conductor that electrically connects the first electrode and the base, and
wherein the second dielectric comprises:
a second heat transfer gas diffusion space configured to supply a heat transfer gas toward the ring support surface; and
a second electrode disposed above the second heat transfer gas diffusion space and electrically connected to a power supply that outputs a common voltage with the base.

12. The plasma processing apparatus of claim 11, further comprising an edge ring placed on the ring support surface.

13. The plasma processing apparatus of claim 12, wherein the second electrode is a bias electrode for the edge ring.

14. The plasma processing apparatus of claim 12, wherein an area of the ring support surface of the second dielectric is smaller than an area of a lower surface of the edge ring supported by the ring support surface.

15. The plasma processing apparatus of claim 11, wherein the first electrode and the second electrode are disposed in a same plane.

16. The plasma processing apparatus of claim 11, wherein the first dielectric further includes a bias electrode for substrate disposed above the first electrode.

17. The plasma processing apparatus of claim 11, wherein the first dielectric further includes an electrostatic electrode for substrate disposed above the first electrode.

18. The plasma processing apparatus of claim 11, wherein the second dielectric further includes an electrostatic electrode for ring disposed above the second electrode.

19. The plasma processing apparatus of claim 11, wherein a plurality of conductors is disposed along a circumferential direction of the first dielectric.

20. The plasma processing apparatus of claim 19, wherein the plurality of conductors is disposed at equal intervals along the circumferential direction of the first dielectric.
